(19) United States
(12) Patent Application Publication
(10) Pub. No.: US 2007/0164274 A1
(43) Pub. Date: Jul. 19, 2007

(54) Brightness enforcement diffussion construction

(75) Inventor: Chin-Hui Chen, Yangmei Taoyuan (TW)

Correspondence Address: TROXELL LAW OFFICE PLLC, SUITE 1404, 5205 LEESBURG PIKE, FALLS CHURCH, VA, 22041, US

(73) Assignee: K-BRIDGE ELECTRONICS CO., LTD.

(21) Appl. No.: 11/526,108

(22) Filed: Sep. 25, 2006

(30) Foreign Application Priority Data
Jan. 18, 2006 (TW) 095101979

(51) Int. Cl. H01L 29/08

(52) U.S. Cl. 257/40

(57) ABSTRACT

A brightness enforcement diffusion construction includes a transparent substrate made of plastic material e.g., PET, PMMA, MS, PS or PC, a diffusion layer disposed on one side of the light coupling or illuminating surface of the substrate, and brightness enforcement layer disposed on the other side; the diffusion layer contains multiple diffusion and/or acrylic particles to refract streams of light for producing diffusion results while enforcing the brightness of the streams of light that pass through the brightness enforcement layer.

### BACKGROUND OF THE INVENTION

(a) Field of the Invention

The present invention is related to a brightness enforcement diffusion construction, and more particularly to a diffusion plate comprised of a transparent substrate made of plastic material provided with a diffusion layer and a brightness enforcement layer respectively on the light coupling surface and light illuminant surface of the substrate to effectively refract streams of light to create diffusion and brightness enforcement results.

(b) Description of the Prior Art

Rapid advancement of the multi-media society is mostly benefited from that of semiconductor device or man-machine display. In terms of the display, the cathode ray tube (CRT) for being economic and providing excellent display quality has been dominating the market of display in recent years. However, many problems in space utility and energy consumption are found with the CRT and CRT fails to effectively provide solution to requirements of being lighter, thinner, shorter, and smaller, and lower power consumption when CRT is examined under the environment of personal operation of most of the terminals and displays or on the aspect of environmental protection in prediction of the future of CRT when energy saving is of primary concern. Therefore, the LCD featuring top picture quality, better space utilization, low power consumption, and free of radiation has gradually become the main stream of the market. It should be noted that the liquid crystal panel in LCD does not emit light and a backlight unit is provided to supply the light source needed by the liquid crystal panel to display with sufficient brightness and contrast.

FIG. 1 of the accompanying drawings shows an exploded view of construction of the a conventional backlight unit, wherein a backlight unit 1 is essentially comprised of a frame 11, a reflector layer 12, a light guide plate 13 and multiple optical layers 14. There are three optical layers as illustrated. The existing practice to assemble the backlight unit 1 involves having the reflector layer 12 mounted in the frame 11 and the light guide 13 placed on top of the reflector layer 12 before mounting three optical layers one by one on the light guide plate 13 and finally a metal frame 15 is provided to carry the frame 11, the reflector layer 12, the light guide plate 13 and three optical layers 14 to complete the assembly.

Multiple optical layers (e.g., diffusion plate, brightness enforcement layer, or reflective polarization layer) are usually provided on top of the light guide plate 13 to improve the performance of luminance and brightness for the backlight unit 1. As illustrated, three optical layers require three rounds of assembly since each of those three optical layers is related to an independent member. The tedious assembly process is the primary factor attributable to the higher costs and work hours for the assembly of the backlight unit 1. Furthermore, it takes also three times of cutting for three optical layers to result in higher cutting work hours and costs.

### SUMMARY OF THE INVENTION

The primary purpose of the present invention is to provide a diffusion plate that provides diffusion and brightness enforcement results at the same time to minimize the use of the diffusion layer and brightness enforcement layer as found with the prior art for effective cost reduction.

To achieve the purpose, the present invention includes a transparent substrate, a diffusion layer, and a brightness enforcement layer. The substrate is made of a plastic material e.g., PET (polyethylene terephthalate), PMMA (polymethyl methacrylate), MS (copolymer of methacrylate and styrene), PS (polystyrene) or PC (polycarbonate) and is provided on both sides respectively a light coupling surface and a light illuminating surface. The diffusion layer is disposed on one side of the light coupling or the light illuminating surface of the substrate while the brightness enforcement layer disposed on the other side. The diffusion layer contains multiple diffusion and/or acrylic particles to refract streams of light for producing diffusion results while enforcing the brightness of the streams of light that pass through the brightness enforcement layer.

### BRIEF DESCRIPTION OF THE DRAWINGS

FIG. 1 is an exploded view of a construction of a backlight unit of the prior art.

FIG. 2 is a sectional view showing a first preferred embodiment of the present invention.

FIGS. 3(A), 3(B), 3(C) and 3(D) are views showing operating status of the first preferred embodiment of the present invention.

FIG. 4 is a sectional view of a second preferred embodiment of the present invention.

FIG. 5 is a flow chart showing the manufacturing process of the present invention.

FIG. 6 is a schematic view showing a brightness-enforcement layer is disposed to a transparent substrate of the present invention.

FIG. 7 is a perspective view showing the construction of the brightness enforcement layer of the present invention.

FIGS. 8(A) and 8(B) are further perspective views showing the construction of the brightness enforcement layer of the present invention.

FIG. 9 is another perspective view yet showing the construction of the brightness enforcement layer of the present invention.

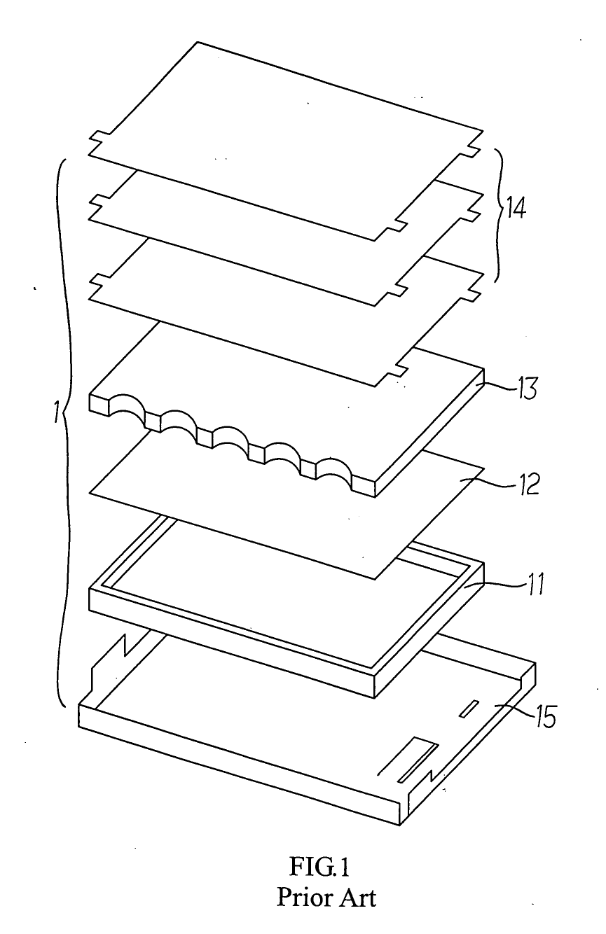

### DETAILED DESCRIPTION OF THE PREFERRED EMBODIMENTS

The prevent invention provides a brightness enforcement diffusion construction and its manufacturing process that is applied in a backlight unit. When streams of light pass the present invention turn into highly consistent and evenly distributed to minimize the use of diffusion and brightness enforcement films in the conventional optical films thus to achieve the purpose of cost reduction while promoting the quality of the brightness of the backlight unit.

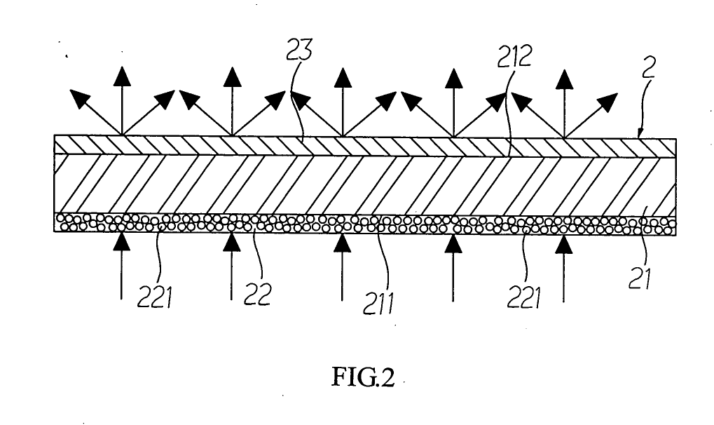

A brightness enforcement diffusion construction 2 of a preferred embodiment of the present invention is comprised of a transparent substrate 21, a diffusion layer 22, and a brightness enforcement layer 23 as illustrated in FIG. 2. The transparent substrate 21 is made of plastic material, e.g., PET (polyethylene terephthalate), PMMA (polymethyl methacrylate), MS (copolymer of methacrylate and styrene), PS (polystyrene) or PC (polycarbonate) and has on both sides respectively provided with a light-coupling surface 211 and an illuminating surface 212. The diffusion layer 22 disposed on top of the light-coupling surface of the substrate contains multiple diffusion particles 221 and/or acrylic particles. The brightness enforcement layer 23 disposed on the illuminating surface 212 is comprised of a brightness enforcement film attached thereto by adhesion, coating, lamination, rolling or coating followed with lamination or rolling, or directly molded on the illuminating surface.

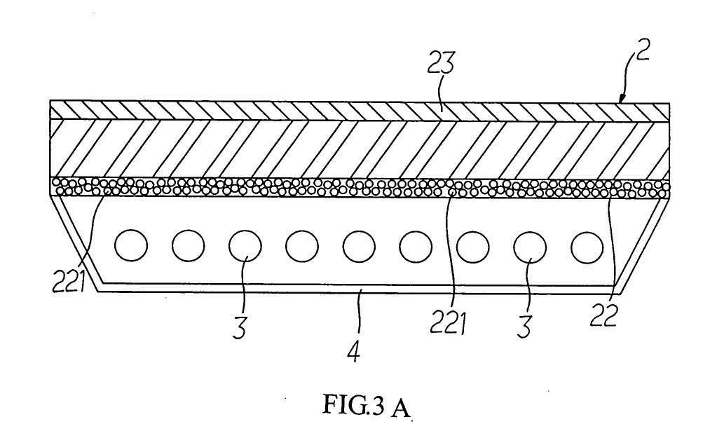

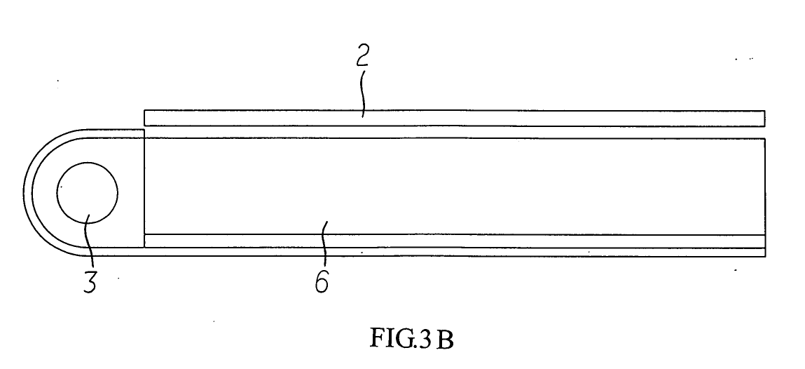

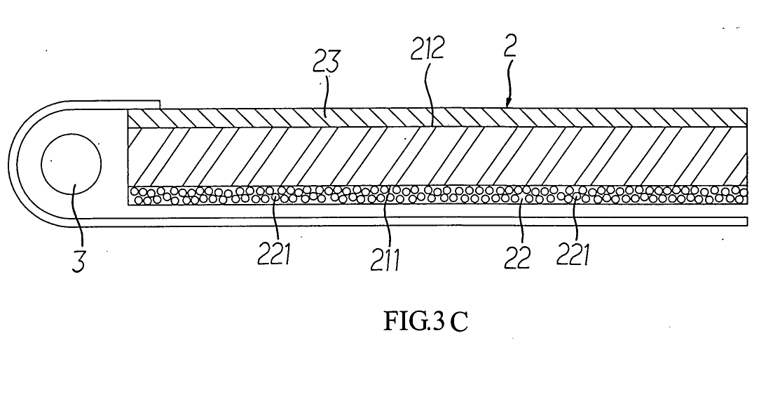

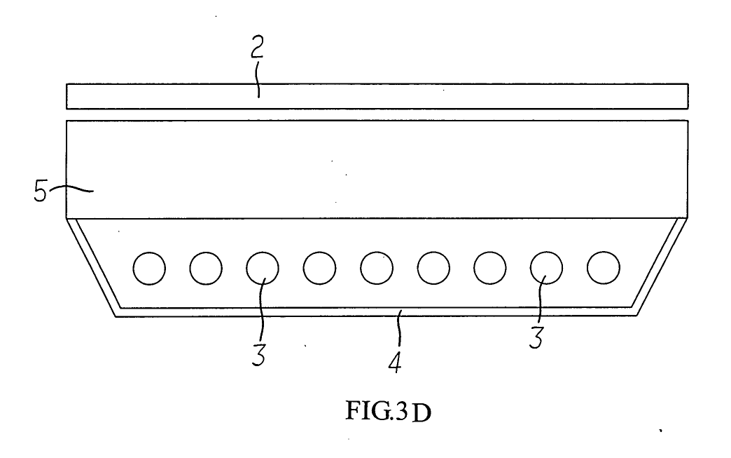

Depending on the end use purpose, the thickness of the transparent substrate may vary to produce the brightness enforcement diffusion construction either in plate or sheet form. When applied to a direct-type backlight unit as illustrated in FIG. 3 (A), the brightness enforcement diffusion construction 2 is made in a plate form and disposed at where over a reflective mask 4 provided with multiple light sources 3; or made in a sheet form and placed over a diffusion plate 5 on the top of the reflective mask 4 as illustrated in FIG. 3 (B). When applied in a side type backlight, the brightness enforcement diffusion construction 2 as illustrated in FIG. 3 (C) is made in plate form and those multiple light sources 3 are disposed on one side to the brightness enforcement diffusion construction 2; or the brightness enforcement diffusion construction 2 is made in sheet form and placed on the top of a light guide plate 6 as illustrated in FIG. 3 (D) for the streams of light from those multiple light sources 3 to be refracted by those diffusion particles 221 or acrylic particles. Also referring to FIG. 2, streams of light are refracted for diffusion and then enforced with their brightness through the brightness enforcement layer 23 to be emitted constantly in high luminance from those multiple light sources 3. Accordingly, the brightness enforcement diffusion construction 2 is effectively to reduce the use of diffusion film and brightness enforcement film as found with the conventional multi-layer optical films thus to reduce assembly cost while promoting the luminance quality of the backlight unit.

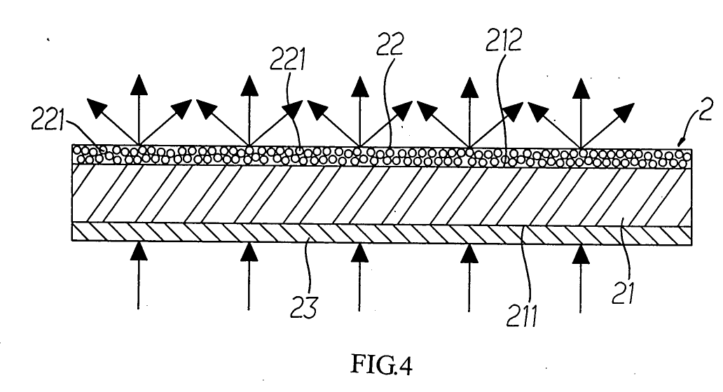

Now referring to FIG. 4, the diffusion layer 22 is disposed on the illuminating surface 212 of the transparent substrate while the brightness enforcement layer 23 is disposed on the light-coupling surface 211 to achieve the same light diffusion with enforced brightness.

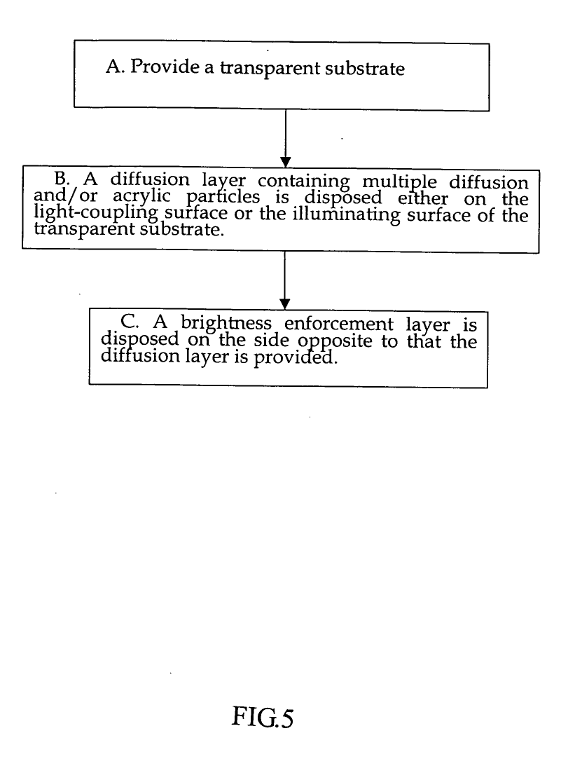

In practice, as also illustrated in FIG. 5, a manufacturing process for the brightness enforcement diffusion construction 2 is comprised of the following steps:

Step A: a transparent substrate made of plastic material, e.g., PET (polyethylene terephthalate), PMMA (polymethyl methacrylate), MS (copolymer of methacrylate and styrene), PS (polystyrene) or PC (polycarbonate) is provided that has a light-coupling surface and an illuminating surface respectively on both sides;

Step B: a diffusion layer containing multiple diffusion and/or acrylic particles is disposed on either of the light-coupling or the illuminating surface of the transparent substrate by coating, spraying or atomizing method; and

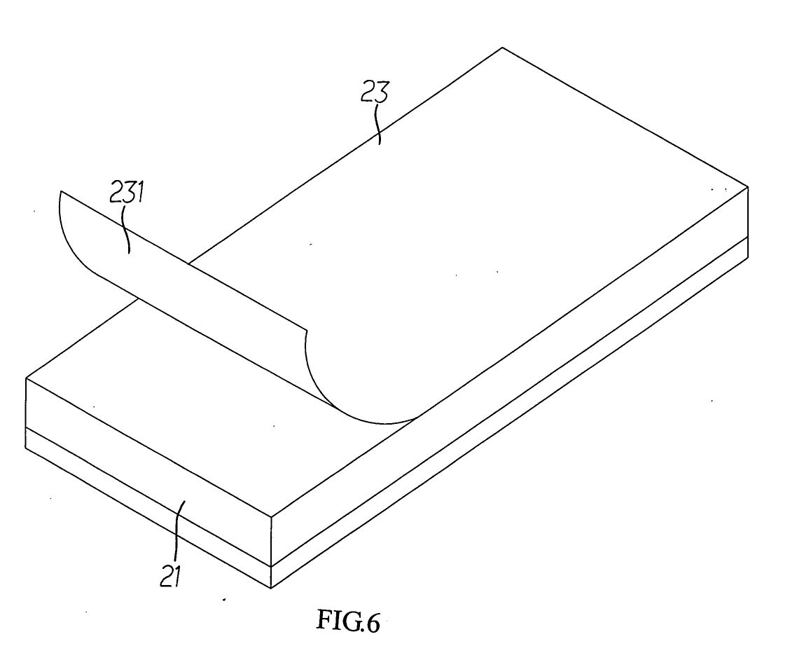

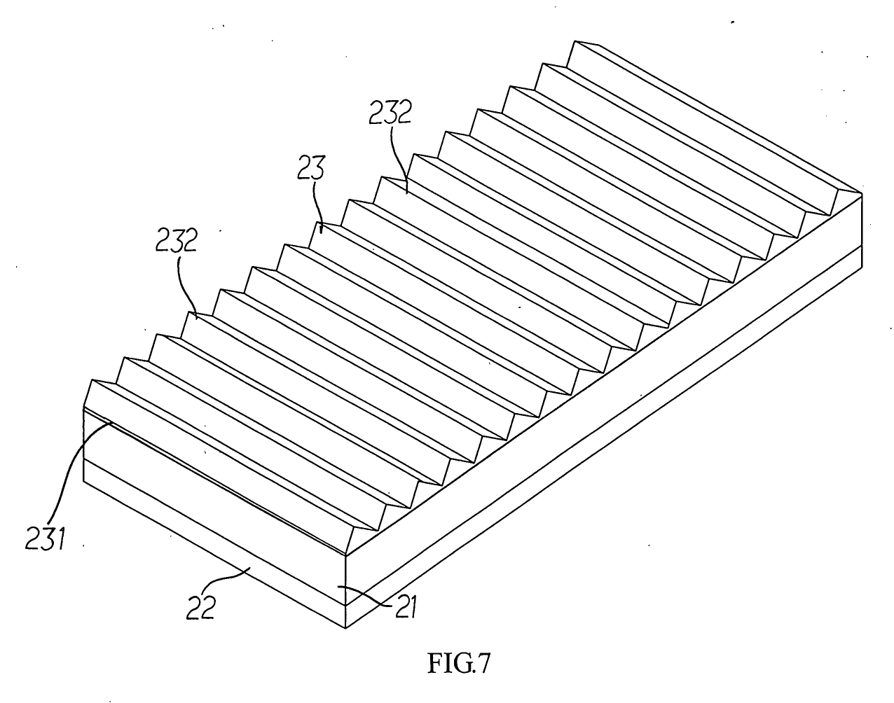

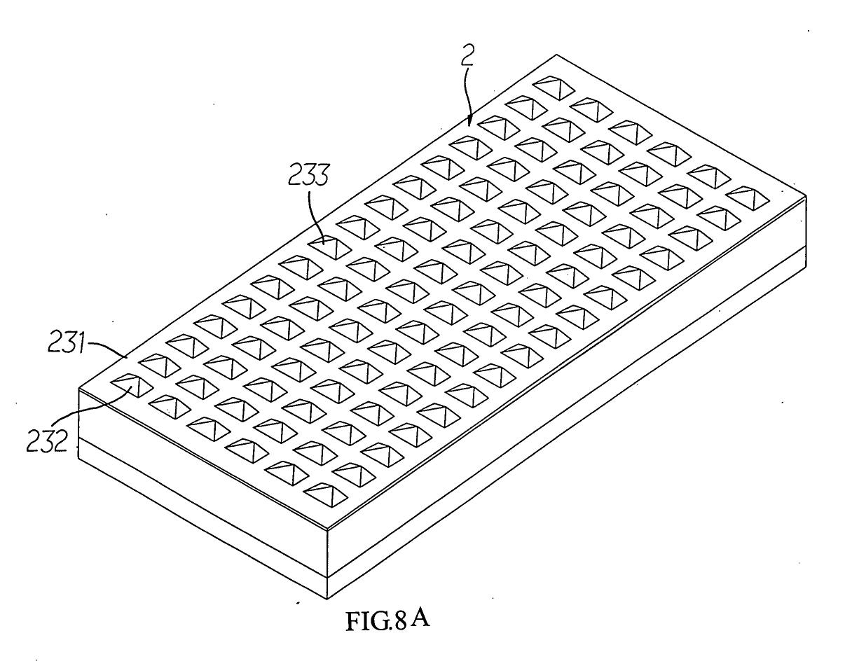

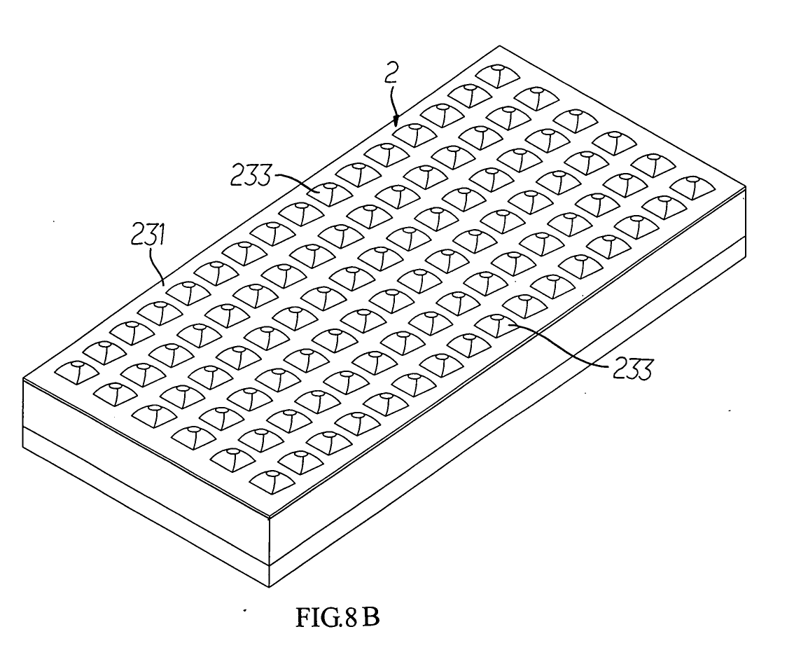

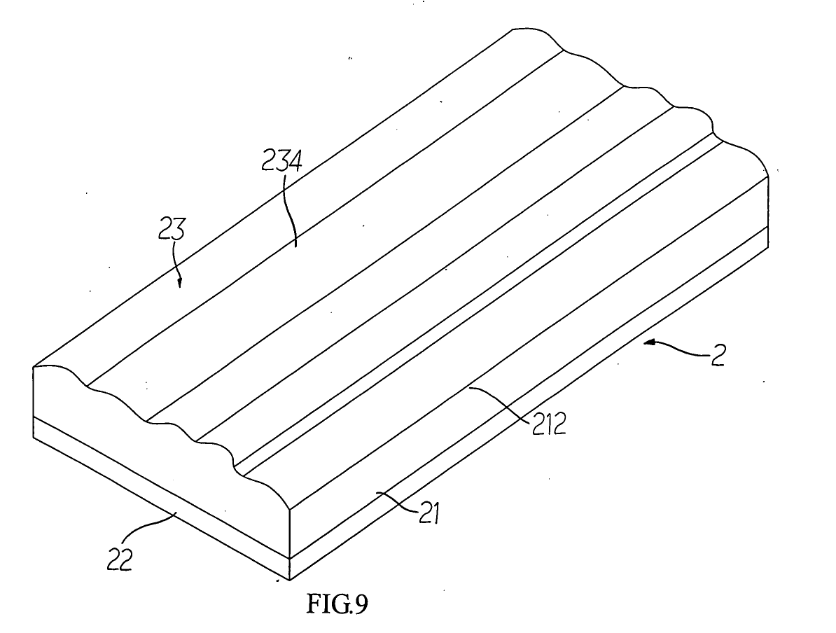

Step C: as illustrated in FIG. 6, a brightness enforcement layer is disposed on the opposite surface to that the diffusion layer is provided on the transparent substrate 2. The brightness enforcement layer 23 is formed by having a brightness enforcement film 231 attached to the transparent substrate 2 by adhesion, coating, lamination, rolling, or by adhesion or coating followed with lamination or rolling, or direct molding to complete the manufacturing process. Alternatively, the brightness enforcement film 231 is provided with a pattern 232 of multiple prisms as illustrated in FIG. 7 or a geometric pattern 233 as illustrated in FIGS. 8 (A) and (B) in a form or structure that is capable of enforcing brightness by rolling or direct molding to provide brightness enforcement results; or as illustrated in FIG. 9 a structure 234 giving brightness enforcement is disposed on the illuminating surface 212 by rolling, lamination or direct molding.

Accordingly, the present invention may be applied in the direct type or side type of backlight unit to refract streams of light by taking advantage of diffusion and/or acrylic particles while promoting luminance of the streams of light passing through the brightness enforcement layer.

The prevent invention provides a brightness enforcement diffusion construction and its manufacturing process, and the application for a patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. A brightness enforcement diffusion construction includes a transparent substrate made of plastic material and having both sides respectively a light coupling surface and an illuminating surface; a diffusion layer being disposed on the light coupling or the illuminating surface, and containing multiple diffusion and/or acrylic particles to refract streams of light for light diffusion; and a brightness enforcement layer disposed on the opposite side where the diffusion layer is provided.

2. The brightness enforcement diffusion construction as claimed in claim 1, wherein the transparent substrate is made of PET (polyethylene terephthalate), PMMA (polymethyl methacrylate), MS (copolymer of methacrylate and styrene), PS (polystyrene) or PC (polycarbonate).

3. The brightness enforcement diffusion construction as claimed in claim 1, wherein the diffusion layer is disposed on the light-coupling surface of the transparent substrate, and the brightness enforcement layer is disposed on the illuminating surface of the transparent substrate.

4. The brightness enforcement diffusion construction as claimed in claim 1, wherein the diffusion layer is disposed on the illuminating surface of the transparent substrate, and the brightness enforcement layer is disposed on the light-coupling surface of the transparent substrate.

5. The brightness enforcement diffusion construction as claimed in claim 1, wherein the construction is disposed on top of a reflective mask provided with multiple light sources.

6. The brightness enforcement diffusion construction as claimed in claim 1, wherein those multiple light sources are disposed to the side of the construction.

7. A process for the manufacturing of the brightness enforcement diffusion construction is comprised of the following steps:
Step A: a transparent substrate made of plastic material is provided that has a light-coupling surface and an illuminating surface respectively on both sides;
Step B: a diffusion layer containing multiple diffusion and/or acrylic particles is disposed on either of the light-coupling or the illuminating surface of the transparent substrate; and
Step C: a brightness enforcement layer is disposed on the opposite surface to that the diffusion layer is provided on the transparent substrate.

8. The manufacturing process of the brightness enforcement construction as claimed in claim 7, wherein the transparent substrate is made of PET (polyethylene terephthalate), PMMA (polymethyl methacrylate), MS (copolymer of methacrylate and styrene), PS (polystyrene) or PC (polycarbonate).

9. The manufacturing process of the brightness enforcement construction as claimed in claim 7, wherein the diffusion layer is disposed on the light-coupling surface of the transparent substrate, and the brightness enforcement layer is disposed on the illuminating surface of the transparent substrate.

10. The manufacturing process of the brightness enforcement construction as claimed in claim 7, wherein the diffusion layer is disposed on the illuminating surface of the transparent substrate, and the brightness enforcement layer is disposed on the light-coupling surface of the transparent substrate.

11. The manufacturing process of the brightness enforcement construction as claimed in claim 7, wherein the construction is disposed on top of a reflective mask provided with multiple light sources.

12. The manufacturing process of the brightness enforcement construction as claimed in claim 7, wherein those multiple light sources are disposed to the side of the construction.

13. The manufacturing process of the brightness enforcement construction as claimed in claim 7, wherein those multiple diffusion and/or acrylic particles are disposed on the transparent substrate by a coating, spraying or atomizing method.

14. The manufacturing process of the brightness enforcement construction as claimed in claim 7, wherein the brightness enforcement layer is related to a brightness enforcement film disposed on the transparent substrate either by direct molding or by adhesion, coating, lamination, rolling, lamination or rolling after adhesion or coating.

15. The manufacturing process of the brightness enforcement construction as claimed in claim 7, wherein the brightness enforcement film contains a pattern of multiple prisms or a geometric pattern in a form or structure that is capable of enforcing the brightness.

16. The manufacturing process of the brightness enforcement construction as claimed in claim 7, wherein the brightness enforcement layer is formed or disposed on the transparent substrate either by rolling, lamination or direct molding.

17. A brightness enforcement diffusion construction includes a transparent substrate made of plastic material and having both sides respectively a light coupling surface and an illuminating surface; a diffusion layer being disposed on the light coupling or the illuminating surface, and containing multiple diffusion particles or multiple diffusion particles containing acrylic particles to refract streams of light for light diffusion; and a brightness enforcement layer disposed on the opposite side where the diffusion layer is provided.

18. The manufacturing process of the brightness enforcement construction as claimed in claim 17, wherein the brightness enforcement layer is disposed with the brightness enforcement film before being further provided with the form or structure that is capable of enforcing brightness.
